(19) United States
(12) Patent Application Publication
(10) Pub. No.: US 2026/0130284 A1
(43) Pub. Date: May 7, 2026

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Hanmin LEE, Suwon-si (KR); Sangsick PARK, Suwon-si (KR)

(73) Assignee: SAMSUNG ELECTRONICS CO., LTD., Suwon-si (KR)

(21) Appl. No.: 19/317,771

(22) Filed: Sep. 3, 2025

(30) Foreign Application Priority Data
Nov. 6, 2024 (KR) 10-2024-0156464

(51) Int. Cl. H01L 25/065; H01L 23/00; H01L 23/28; H01L 23/48

(52) U.S. Cl. CPC H10W 90/00; H10W 20/20; H10W 74/00; H10W 72/244; H10W 74/15; H10W 90/722; H10W 90/732

(57) ABSTRACT

A semiconductor package includes a base chip, a first semiconductor chip group including a plurality of first semiconductor chips stacked on the base chip in a vertical direction, a second semiconductor chip group including a plurality of second semiconductor chips stacked on the first semiconductor chip group in the vertical direction, a plurality of first connection bumps on lower surfaces of the plurality of first semiconductor chips, a plurality of second connection bumps on lower surfaces of the plurality of second semiconductor chips, a first adhesive layer surrounding the plurality of first connection bumps and the first semiconductor chip group, and a second adhesive layer surrounding the plurality of second connection bumps and the second semiconductor chip group.

### CROSS-REFERENCE TO RELATED APPLICATION

This application is based on and claims priority under 35 U.S.C. § 119 to Korean Patent Application No. 10-2024-0156464, filed on Nov. 6, 2024, in the Korean Intellectual Property Office, the disclosure of which is incorporated by reference herein in its entirety.

### BACKGROUND

The present disclosure relates to a semiconductor package and a method of fabricating the semiconductor package, and more particularly, to a semiconductor package in which a plurality of semiconductor chips are stacked, and a method of fabricating the semiconductor package.

Recently, the demand for portable devices has been rapidly increasing in the electronic product market, and this has led to continuous demands for miniaturization and weight reduction of electronic components mounted on these electronic products. In order to miniaturize and lighten electronic components, semiconductor packages mounted on the electronic components are required to be smaller in size while also being able to process large amounts of data. As these semiconductor packages become more highly integrated, improvements in reliability and processability of the semiconductor packages are required.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor package with enhanced reliability, and a method of fabricating the semiconductor package.

Additional aspects will be set forth in part in the description which follows and, in part, will be apparent from the description, or may be learned by practice of the presented embodiments.

According to an aspect of an example embodiment, a semiconductor package may include a base chip, a first semiconductor chip group including a plurality of first semiconductor chips stacked on the base chip in a vertical direction, a second semiconductor chip group including a plurality of second semiconductor chips stacked on the first semiconductor chip group in the vertical direction, a plurality of first connection bumps on lower surfaces of the plurality of first semiconductor chips, a plurality of second connection bumps on lower surfaces of the plurality of second semiconductor chips, a first adhesive layer surrounding the plurality of first connection bumps and the first semiconductor chip group, and a second adhesive layer surrounding the plurality of second connection bumps and the second semiconductor chip group.

According to an aspect of an example embodiment, a semiconductor package may include a base chip, a first semiconductor chip and a second semiconductor chip stacked on the base chip in a vertical direction, a plurality of first connection bumps between the base chip and the first semiconductor chip, and between the first semiconductor chip and the second semiconductor chip, a first adhesive layer surrounding the plurality of first connection bumps, and an encapsulation layer covering an upper surface of the base chip, the first semiconductor chip, the second semiconductor chip, and the first adhesive layer, where the first adhesive layer includes a single body covering a lower surface and side surfaces of the first semiconductor chip and a lower surface and side surfaces of the second semiconductor chip.

According to an aspect of an example embodiment, a method of fabricating a semiconductor package may include preparing a base chip, providing a first semiconductor chip on the base chip in a vertical direction, providing a second semiconductor chip on the first semiconductor chip in the vertical direction, and thermally compressing the first semiconductor chip and the second semiconductor chip onto the base chip by performing first thermal compression, where the performing of the first thermal compression includes forming a first adhesive layer as a single body covering a lower surface and side surfaces of the first semiconductor chip, and a lower surface and side surfaces of the second semiconductor chip.

### BRIEF DESCRIPTION OF THE DRAWINGS

The above and other aspects, features, and advantages of certain example embodiments of the present disclosure will be more apparent from the following description taken in conjunction with the accompanying drawings, in which:

FIG. 1 is a cross-sectional view illustrating a configuration of a semiconductor package according to one or more embodiments;

FIG. 2 is an enlarged cross-sectional view of portion “EX1” of FIG. 1 according to one or more embodiments;

FIG. 3 is a graph showing a horizontal length of a vertical portion of an adhesive layer of a semiconductor package according to one or more embodiments;

FIG. 4 is a cross-sectional view illustrating a configuration of a semiconductor package according to one or more embodiments;

FIG. 5 is an enlarged cross-sectional view of portion “EX2” of FIG. 4 according to one or more embodiments; and

FIGS. 6 through 11 are cross-sectional views sequentially illustrating a method of fabricating a semiconductor package according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

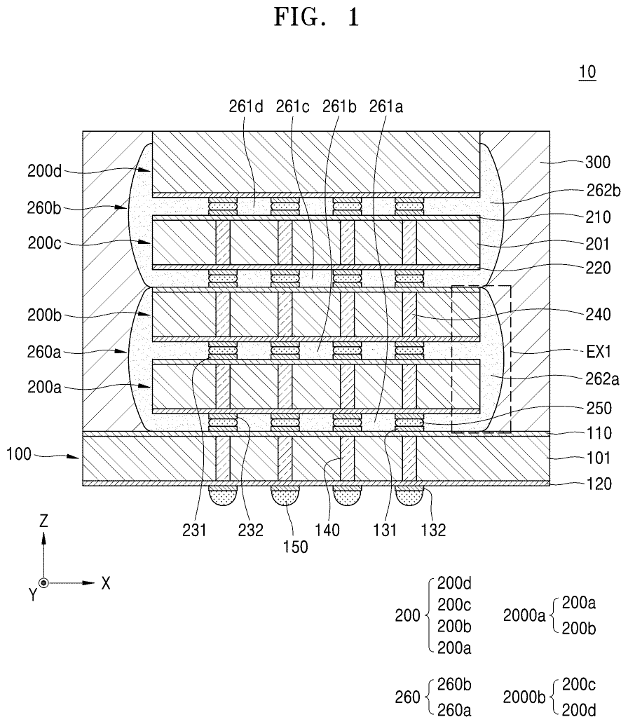

FIG. 1 is a cross-sectional view illustrating a configuration of a semiconductor package 10 according to one or more embodiments.

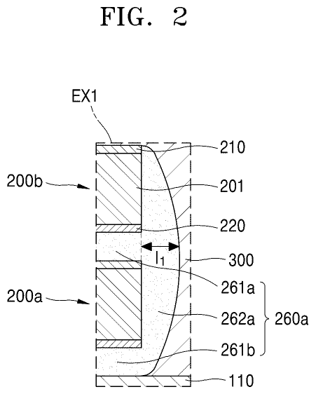

FIG. 2 is an enlarged cross-sectional view of portion “EX1” of FIG. 1 according to one or more embodiments.

Referring to FIGS. 1 and 2, the semiconductor package 10 according to one or more embodiments may include a base chip 100, a plurality of semiconductor chips 200, a plurality of adhesive layers 260, and an encapsulation layer 300.

In one or more embodiments, the base chip 100 may include a semiconductor material such as a silicon (Si) wafer or the like. The base chip 100 may have a greater width than that of each of the plurality of semiconductor chips 200.

In one or more embodiments, the base chip 100 may include a first semiconductor substrate 101, a first passivation layer 110, a first front structure 120, first front pads 132, first rear pads 131, and first through electrodes 140. In this case, the first through electrodes 140 may mean through silicon vias (TSVs). However, embodiments are not limited thereto. Lower bumps 150 may be arranged under the base chip 100. The lower bumps 150 may be connected to the first front pads 132 and electrically connected to the base chip 100.

In one or more embodiments, the base chip 100 may be, for example, a buffer chip including a plurality of logic devices and/or memory devices arranged in the first front structure 120. Thus, the base chip 100 may be configured to transmit signals from the plurality of semiconductor chips 200 stacked on the base chip 100 to the outside through the lower bumps 150 and to transmit signals and power from the outside to the plurality of semiconductor chips 200. The base chip 100 may perform both a logic function and a memory function using logic devices and memory devices. However, embodiments are not limited thereto, and the base chip 100 may perform only a logic function by including only the logic devices. In one or more embodiments, the base chip 100 may be an interposer for mounting the plurality of semiconductor chips 200.

In one or more embodiments, the first semiconductor substrate 101 may include a semiconductor element such as Si or germanium (Ge), or a compound semiconductor such as silicon carbide (SiC), gallium arsenide (GaAs), indium arsenide (InAs), or indium phosphide (InP). The first semiconductor substrate 101 may have a silicon on insulator (SOI) structure. The first semiconductor substrate 101 may include a conductive region, for example, a well doped with impurities, or a structure doped with impurities. The first semiconductor substrate 101 may include various device isolation structures such as shallow trench isolation (STI) structures.

In one or more embodiments, the first front structure 120 may be arranged on a lower surface of the first semiconductor substrate 101, and may include various types of devices. For example, the first front structure 120 may include various active devices and/or passive devices such as a field effect transistor (FET) such as a planar FET or FinFET, a flash memory, a memory device such as dynamic random access memory (DRAM), static random access memory (SRAM), electrically erasable programmable read-only memory (EEPROM), phase-change random access memory (PRAM), magnetoresistive random access memory (MRAM), ferroelectric random access memory (FeRAM), resistive random access memory (RRAM), a logic device such as AND, OR, NOT or the like, system large scale integration (LSI), a complementary metal oxide semiconductor (CMOS) imaging sensor (CIS), a micro-electro-mechanical system (MEMS), and the like.

In one or more embodiments, the first front structure 120 may include interlayer insulating layers and multi-layered wiring layers electrically connected to the above-described devices. The wiring layers may be configured to electrically connect the devices, to electrically connect the devices to the conductive region of the first semiconductor substrate 101, or to electrically connect the devices to the lower bumps 150. In this case, the first front structure 120 may be protected as a separate passivation layer including at least one of silicon oxide, silicon nitride, and silicon oxynitride.

In one or more embodiments, the lower bumps 150 may be arranged on the first front pads 132 and may be electrically connected to the wiring layers inside the first front structure 120 or to the first through electrodes 140. The lower bumps 150 may have the shape of solder balls. However, embodiments are not limited thereto. For example, the lower bumps 150 may have a structure including a pillar and a solder. The semiconductor package 10 may be mounted on an external substrate such as a main board through the lower bumps 150.

In one or more embodiments, the first passivation layer 110 may be arranged on an upper surface of the first semiconductor substrate 101. The first passivation layer 110 may be opposite to front surfaces of the plurality of semiconductor chips 200 and protect the first semiconductor substrate 101.

In one or more embodiments, the first front pads 132 may be arranged on the first front structure 120, and the first rear pads 131 may be arranged on the first passivation layers 110. The first front pads 132 and the first rear pads 131 may be electrically connected to each other through the first through electrodes 140. The first front pads 132 and the first rear pads 131 may include, for example, at least one of aluminum (Al), copper (Cu), nickel (Ni), tungsten (W), platinum (Pt), and gold (Au).

In one or more embodiments, the first through electrodes 140 may pass through the first semiconductor substrate 101 in a vertical direction (Z direction) and provide an electrical path connecting the first front pads 132 to the first rear pads 131. Each of the first through electrodes 140 may include a conductive plug and a barrier layer surrounding the conductive plug. The conductive plug may include a metal material, for example, W, Ti, Al, or Cu. The conductive plug may be formed using a plating process, a plasma vapor deposition (PVD) process, or a chemical vapor deposition (CVD) process. The barrier layer may include an insulating barrier layer or/and a conductive barrier layer. The insulating barrier layer may include an oxide layer, a nitride layer, a carbon layer, polymer, or a combination thereof. In one or more embodiments, the conductive barrier layer may be arranged between the insulating barrier layer and the conductive plug. The conductive barrier layer may include, for example, a metal compound such as tungsten nitride (WN), titanium nitride (TiN) or tantalum nitride (TaN). The barrier layer may be formed using a PVD process, or a CVD process.

In one or more embodiments, the plurality of semiconductor chips 200 may be stacked on the base chip 100. The plurality of semiconductor chips 200 may be sequentially stacked in the vertical direction (Z direction) and may form a stacked structure. For example, a first semiconductor chip 200a may be stacked on the base chip 100, a second semiconductor chip 200b may be stacked on the first semiconductor chip 200a, a third semiconductor chip 200c may be stacked on the second semiconductor chip 200b, and a fourth semiconductor chip 200d may be stacked on the third semiconductor chip 200c. In this case, a rear surface of the base chip 100 and a front surface of the first semiconductor chip 200a may be arranged to oppose each other.

In one or more embodiments, each of the plurality of semiconductor chips 200 may include a second semiconductor substrate 201, a second front structure 220, and second front pads 232. Each of the remaining semiconductor chips 200a, 200b, and 200c except for the fourth semiconductor chip 200d arranged at the uppermost position among the plurality of semiconductor chips 200 may include a second passivation layer 210, second rear pads 231, and second through electrodes 240. In this case, the second through electrodes 240 may be TSVs. However, embodiments are not limited thereto. The plurality of semiconductor chips 200 may be electrically connected to each other through a plurality of connection bumps 250 arranged under each of the plurality of semiconductor chips 200.

In one or more embodiments, the second semiconductor substrate 201 may include, for example, a semiconductor element such as Si or Ge, or a compound semiconductor such as SiC, GaAs, InAs, or InP. The second semiconductor substrate 201 may have a SOI structure. The second semiconductor substrate 201 may include a conductive region, for example, a well doped with impurities, or a structure doped with impurities. The second semiconductor substrate 201 may include various device isolation structures such as STI structures.

In one or more embodiments, the second front structure 220 may include a plurality of memory devices. For example, the second front structure 220 may include volatile memory devices such as DRAM or SRAM, or nonvolatile memory devices such as PRAM, MRAM, FeRAM or RRAM. For example, in the semiconductor package 10 according to one or more embodiments, DRAM devices may be arranged in the second front structure 220 of the plurality of semiconductor chips 200. The second front structure 220 may include interlayer insulating layers and multi-layered wiring layers electrically connected to the above-described memory devices. The memory devices of the second front structure 220 may be electrically connected to the plurality of connection bumps 250 through the wiring layers.

In one or more embodiments, the base chip 100 may include a plurality of logic devices and/or memory devices in the first front structure 120, and may be referred to as a buffer chip or a control chip according to its function, whereas, each of the plurality of semiconductor chips 200 may include a plurality of memory devices in the second front structure 220, and may be referred to as a core chip.

In one or more embodiments, the base chip 100 and the plurality of semiconductor chips 200 may constitute a high bandwidth memory (HBM). For example, the base chip 100 may be a buffer chip for controlling an HBM DRAM, and the plurality of semiconductor chips 200 may be a memory cell chip having a cell of the HBM DRAM controlled by the base chip 100. The base chip 100 may be referred to as a buffer chip, a master chip, or an HBM controller die, and the plurality of semiconductor chips 200 may be referred to as a memory chip, a slave chip, a DRAM dice, or a DRAM slice. The base chip 100 and the plurality of semiconductor chips 200 may be referred to as an HBM DRAM device or an HBM DRAM chip.

In one or more embodiments, the plurality of semiconductor chips 200 may be sequentially stacked on the base chip 100. The fourth semiconductor chip 200d arranged at the uppermost position may have a greater thickness than the remaining semiconductor chips 200a, 200b, and 200c. However, embodiments are not limited thereto. Additionally, the fourth semiconductor chip 200d arranged at the uppermost position may not include the second rear pads 231 and the second through electrodes 240, unlike the remaining semiconductor chips 200a, 200b, and 200c. In one or more embodiments, one semiconductor package 10 includes four semiconductor chips 200. However, the number of semiconductor chips is not limited to illustration of the drawing and may be variously changed according to various embodiments. For example, one semiconductor package 10 may include eight, twelve, sixteen semiconductor chips.

In one or more embodiments, the plurality of connection bumps 250 may be arranged on one front surface and/or rear surface of the plurality of semiconductor chips 200. The plurality of connection bumps 250 may be arranged between the second rear pads 231 of the semiconductor chip arranged at a lower position among the plurality of semiconductor chips 200 and the second front pads 232 of the semiconductor chip arranged at an upper position among the plurality of semiconductor chips 200. The plurality of connection bumps 250 may be arranged between the first semiconductor chip 200a arranged at the lowermost position and the base chip 100. The plurality of connection bumps 250 may electrically connect the plurality of semiconductor chips 200 to the base chip 100. The plurality of connection bumps 250 may include, for example, solders. However, embodiments are not limited thereto. For example, the plurality of connection bumps 250 may include both pillars and solders. The pillar has a cylindrical shape, or a polygonal pillar shape such as a square pillar shape or an octagonal pillar shape, and may include, for example, Ni, Cu, Pd, Pt, Au, or a combination thereof. The solder may have a spherical or ball shape and may include, for example, tin (Sn), indium (In), bismuth (Bi), antimony (Sb), copper (Cu), silver (Ag), zinc (Zn), lead (Pb) and/or alloys thereof. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like.

In one or more embodiments, the plurality of adhesive layers 260 may be configured to fix the plurality of semiconductor chips 200 to the base chip 100. The plurality of adhesive layers 260 may surround side surfaces of the plurality of connection bumps 250. The plurality of adhesive layers 260 may be arranged between the base chip 100 and the plurality of semiconductor chips 200 to contact and surround the plurality of connection bumps 250. The plurality of adhesive layers 260 may include a non-conductive film (NCF). However, embodiments are not limited thereto. For example, the adhesive layer 260 may include at least one of an epoxy resin, silica (SiO₂), and acrylic copolymer, or a combination thereof.

In one or more embodiments, the plurality of adhesive layers 260 may simultaneously cover a lower surface and side surfaces of each of the plurality of semiconductor chips 200 adjacent in the vertical direction (Z direction) among the plurality of semiconductor chips 200. The plurality of adhesive layers 260 may include a first adhesive layer 260a and a second adhesive layer 260b.

In one or more embodiments, the first adhesive layer 260a may surround a first semiconductor chip group 2000a arranged at a lower position among the plurality of semiconductor chips 200, and the second adhesive layer 260b may surround a second semiconductor chip group 2000b arranged on the first semiconductor chip group. The first semiconductor chip group 2000a may include a first semiconductor chip 200a and a second semiconductor chip 200b, and the second semiconductor chip group 2000b may include a third semiconductor chip 200c and a fourth semiconductor chip 200d. However, embodiments are not limited thereto, and each of the first semiconductor chip group 2000a and the second semiconductor chip group 2000b may include one or three or more semiconductor chips, and the number of semiconductor chips included in the first semiconductor chip group 2000a and the number of semiconductor chips included in the second semiconductor chip group 2000b may be different from each other.

For example, the first adhesive layer 260a may simultaneously cover a lower surface and side surfaces of the first semiconductor chip 200a and a lower surface and side surfaces of the second semiconductor chip 200b. In addition, the second adhesive layer 260b may simultaneously cover a lower surface and side surfaces of the third semiconductor chip 200c and a lower surface and side surfaces of the fourth semiconductor chip 200d. The first adhesive layer 260a and the second adhesive layer 260b may be formed as a single body to simultaneously cover the lower surface and side surfaces of each of the adjacent plurality of semiconductor chips 200. That is, the adhesive layers may be single bodies that include various portions covering various components of the chips. For example, the first adhesive layer 260a may be a single body with vertical components (described below) and horizontal components (described below) that cover a lower surface and side surfaces of the first semiconductor chip 200a and a lower surface and side surfaces of the second semiconductor chip 200b (e.g., simultaneously cover).

In one or more embodiments, each of the plurality of adhesive layers 260 may include a plurality of horizontal portions 261a, 261b, 261c, and 261d for covering lower surfaces of the plurality of semiconductor chips 200 and vertical portions 262a and 262b for covering side surfaces of the plurality of semiconductor chips 200. That is, each of the plurality of adhesive layers 260 may include a plurality of horizontal portions 261a, 261b, 261c, and 261d that overlap the plurality of semiconductor chips 200 in the vertical direction (Z direction), and vertical portions 262a and 262b that cover the side surfaces of the plurality of semiconductor chips 200 and protrude outwards from the plurality of horizontal portions 261a, 261b, 261c, and 261d. The vertical portions 262a and 262b may be mentioned as fillet portions. The degree of protrusion and shape of the vertical portions 262a and 262b may vary depending on process conditions, for example, conditions of a thermal compression process.

In one or more embodiments, the first adhesive layer 260a may include a first horizontal portion 261a, a second horizontal portion 261b, and a vertical portion 262a. The first horizontal portion 261a, the second horizontal portion 261b, and the first vertical portion 262a may be formed as a single body. The second adhesive layer 260b may include a third horizontal portion 261c, a fourth horizontal portion 261d, and a second vertical portion 262d. The third horizontal portion 261c, the fourth horizontal portion 261d, and the second vertical portion 262b may be formed as a single body.

In one or more embodiments, the plurality of horizontal portions 261a, 261b, 261c, and 261d may be arranged in the vertical direction (Z direction) and spaced apart from each other with the plurality of semiconductor chips 200 therebetween. For example, a first semiconductor chip 200a may be disposed between the first horizontal portion 261a and the second horizontal portion 261b, a second semiconductor chip 200b may be disposed between the second horizontal portion 261b and the third horizontal portion 261c, and a third semiconductor chip 200c may be disposed between the third horizontal portion 261c and the fourth horizontal portion 261d.

In one or more embodiments, the first vertical portion 262a may cover side surfaces of the first semiconductor chip 200a and side surfaces of the second semiconductor chip 200b. One surface of the first vertical portion 262a may be connected to each of the first horizontal portion 261a and the second horizontal portion 261b. In addition, the other surface of the first vertical portion 262a opposing the one surface may constitute a curved surface. The second vertical portion 262b may cover side surfaces of the third semiconductor chip 200c and side surfaces of the fourth semiconductor chip 200d. The second vertical portion 262b may cover only part of the side surfaces of the fourth semiconductor chip 200d. However, embodiments are not limited thereto. One surface of the second vertical portion 262b may be connected to each of the third horizontal portion 261c and the fourth horizontal portion 261d. In addition, the other surface of the second vertical portion 262b opposing the one surface may constitute a curved surface. For example, the other surfaces of the first vertical portion 262a and the second vertical portion 262b may have semicircular shapes in a plan view.

In one or more embodiments, a horizontal width l₁ of the first vertical portion 262a may increase and then decrease as the first vertical portion 262a moves away from the bottom surface of the first adhesive layer 260a. That is, a horizontal width l₁ of the first vertical portion 262a may increase and then decrease in the Z direction from the bottom surface of the first adhesive layer 260a. For example, the horizontal width l₁ of the first vertical portion 262a may be maximum at the vertical level of the vertical direction (Z direction) center of the first vertical portion 262a. However, embodiments are not limited thereto. The horizontal width of the second vertical portion 262b may increase and then decrease as the second vertical portion 262b moves away from (e.g., in the Z direction from) the bottom surface of the second adhesive layer 260b. For example, the horizontal width of the second vertical portion 262b may be maximum at the vertical level of the vertical direction (Z direction) center of the second vertical portion 262b. However, embodiments are not limited thereto. The shapes of the first vertical portion 262a and the second vertical portion 262b may be substantially the same or similar. In addition, the horizontal widths of the first vertical portion 262a and the second vertical portion 262b may be substantially the same or similar. However, embodiments are not limited thereto, and the shapes and/or the horizontal widths of the first vertical portion 262a and the second vertical portion 262b may be different from each other.

In a conventional semiconductor package according to a comparative example, fillets of the adhesive layer are formed for each of a plurality of semiconductor chip layers, and as the length of the fillets increases, warpage of the semiconductor package increases, thereby lowering the reliability of the semiconductor package. In addition, cracks occur due to increased stress acting between the interface of the fillet and the encapsulation layer.

On other hand, in the semiconductor package 10 according to one or more embodiments, the plurality of semiconductor chips 200 may be adhered to each other using one adhesive layer 260. For example, the first semiconductor chip 200a and the second semiconductor chip 200b may be simultaneously adhered to each other using a first adhesive layer 260a, and the third semiconductor chip 200c and the fourth semiconductor chip 200d may be simultaneously adhered to each other using the second adhesive layer 260b. Thus, the first and second vertical portion 262a and 262b of the adhesive layer 260 may be formed as a single body to cover side surfaces of two or more semiconductor chips 200, so that the number of fillets may be reduced as compared to the comparative example. In addition, since the first and second vertical portions 262a and 262b are formed as a single body, the horizontal lengths of the first and second vertical portions 262a and 262b may decrease, so that warpage of the semiconductor package 10 may decrease and thus the reliability of the semiconductor package 10 may be increased. In addition, the horizontal lengths of the first and second vertical portions 262a and 262b may decrease, and stress acting between the interface of the first and second vertical portions 262a and 262b and the encapsulation layer 300 of the semiconductor package 10 may be reduced so that cracks may be reduced.

In addition, the first semiconductor chip 200a and the second semiconductor chip 200b may be simultaneously adhered to each other using the first adhesive layer 260a, and the third semiconductor chip 200c and the fourth semiconductor chip 200d may be simultaneously adhered to each other using the second adhesive layer 260b, so that the productivity of the semiconductor package 10 may be enhanced. For example, a process recipe may be controlled in such a way that the plurality of connection bumps 250 arranged between the base chip 100 and the first semiconductor chip 200a and between the first semiconductor chip 200a and the second semiconductor chip 200b may be simultaneously adhered to each other.

In one or more embodiments, the encapsulation layer 300 may cover the upper surface of the base chip 100, and the side surfaces of the plurality of semiconductor chips 200 and the plurality of adhesive layers 260. The encapsulation layer 300 may not cover the upper surface of the fourth semiconductor chip 200d arranged at the uppermost position, and the upper surface of the fourth semiconductor chip 200d may be exposed from the encapsulation layer 300. However, embodiments are not limited thereto, and the encapsulation layer 300 may cover the upper surface of the fourth semiconductor chip 200d with a certain thickness. The encapsulation layer 300 may include an insulating material, for example, an epoxy molding compound (EMC).

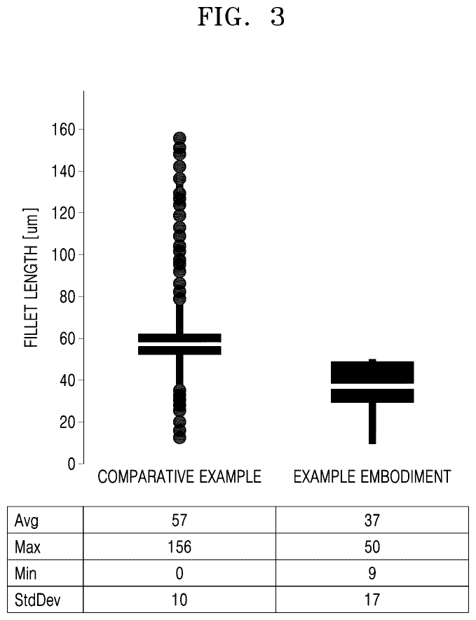

FIG. 3 is a graph showing a horizontal length of a vertical portion of an adhesive layer of a semiconductor package according to one or more embodiments.

Referring to FIG. 3, horizontal lengths of the vertical portions 262a and 262b of the adhesive layer 260 may be checked. The horizontal lengths of the vertical portions 262a and 262b may refer to horizontal (X direction and/or Y direction) lengths from the side surfaces of the semiconductor chip 200 to the other surfaces of the vertical portions 262a and 262b.

In one or more embodiments, an average value Avg of the horizontal lengths of the vertical portions 262a and 262b of the adhesive layer 260 of the semiconductor package 10 according to one or more embodiments may be 37 μm. A maximum value Max of the horizontal lengths of the vertical portions 262 a and 262 b of the adhesive layer 260 may be 50 μm. A minimum value Min of the horizontal lengths of the vertical portions 262a and 262b of the adhesive layer 260 may be 9 μm. A standard deviation StdDev of the horizontal lengths of the vertical portions 262a and 262b of the adhesive layer 260 may be 17 μm.

On the other hand, an average value Avg of the horizontal lengths of the fillets (corresponding to the vertical portions of one or more embodiments) of the adhesive layer of the semiconductor package according to the comparative example may be 57 μm. A maximum value Max of the horizontal lengths of the fillets of the adhesive layer may be 156 μm. A minimum value Min of the horizontal lengths of the fillets of the adhesive layer may be 0 μm. A standard deviation StdDev of the horizontal lengths of the fillets of the adhesive layer may be 16 μm.

That is, it may be confirmed that the horizontal lengths of the vertical portions 262a and 262b decrease by about ⅓ as compared to the comparative example based on the most protruding portion (e.g., maximum value) of the vertical portions 262a and 262b of the adhesive layer 260. As the horizontal lengths of the vertical portions 262a and 262b decrease, warpage of the semiconductor package 10 decreases, and stress acting between the interface of the vertical portions 262a and 262b and the encapsulation layer 300 decreases, so that the reliability of the semiconductor package 10 may increase.

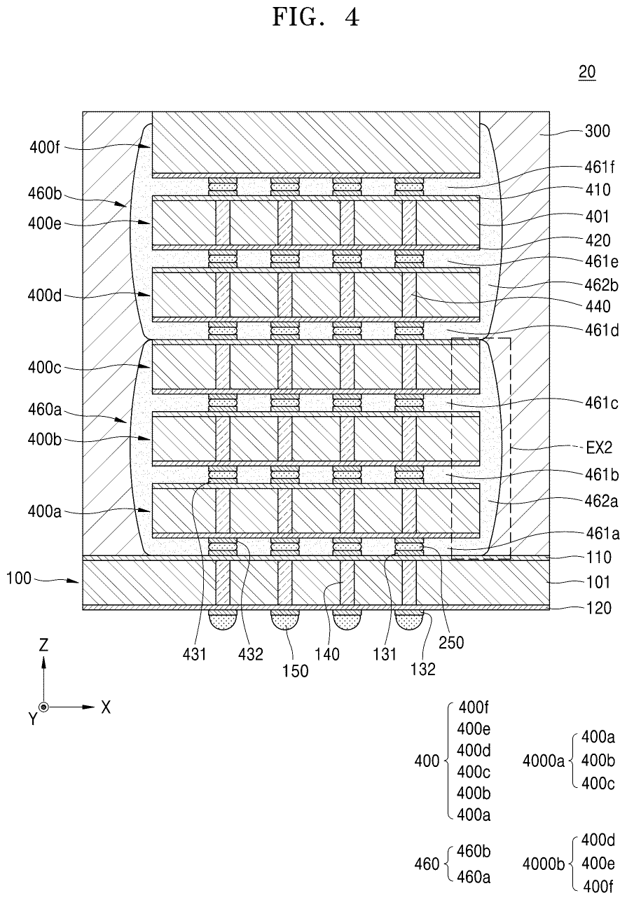

FIG. 4 is a cross-sectional view illustrating a configuration of a semiconductor package according to one or more embodiments.

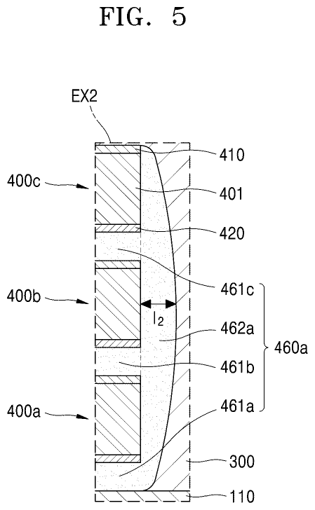

FIG. 5 is an enlarged cross-sectional view of portion “EX2” of FIG. 4 according to one or more embodiments.

In the description with reference to FIGS. 4 and 5, the same reference numerals as in FIGS. 1 and 2 represent the same elements, and a detailed description of similar elements may be omitted.

Referring to FIGS. 4 and 5, a semiconductor package 20 according to one or more embodiments may include a base chip 100, a plurality of semiconductor chips 400, a plurality of adhesive layers 460, and an encapsulation layer 300. The plurality of semiconductor chips 400 and the plurality of adhesive layers 460 may respectively have substantially the same configuration as the plurality of semiconductor chips 200 and the plurality of adhesive layers 460 illustrated in FIGS. 1 and 2, respectively, and a detailed description thereof may be omitted.

In one or more embodiments, the plurality of semiconductor chips 400 may be stacked on the base chip 100. The plurality of semiconductor chips 400 may be sequentially stacked in the vertical direction (Z direction) and may form a stacked structure. For example, a first semiconductor chip 400a may be stacked on the base chip 100, a second semiconductor chip 400b may be stacked on the first semiconductor chip 400a, a third semiconductor chip 400c may be stacked on the second semiconductor chip 400b, a fourth semiconductor chip 400d may be stacked on the third semiconductor chip 400c, a fifth semiconductor chip 400e may be stacked on the fourth semiconductor chip 400d, and a sixth semiconductor chip 400f may be stacked on the fifth semiconductor chip 400e. In this case, a rear surface of the base chip 100 and a front surface of the first semiconductor chip 200a may be arranged to oppose each other.

As shown in FIG. 4, semiconductor chip groups may be provided. For example, a first semiconductor chip group 4000a may include chips 400a, 400b and 400c, and the first semiconductor chip group 4000a may be surrounded by the adhesive layer 460a. A second semiconductor chip group 4000b may include chips 400d, 400e and 400f, and the second semiconductor chip group 4000b may be surrounded by the adhesive layer 460b.

In one or more embodiments, each of the plurality of semiconductor chips 400 may include a second semiconductor substrate 401, a second front structure 420, and second front pads 432. Each of the remaining semiconductor chips 400a, 400b, 400c, 400d, and 400e except for the sixth semiconductor chip 400f arranged at the uppermost position among the plurality of semiconductor chips 400 may include a second passivation layer 410, second rear pads 431, and second through electrodes 440. In this case, the second through electrodes 240 may be TSVs. However, embodiments are not limited thereto. The plurality of semiconductor chips 400 may be electrically connected to each other through a plurality of connection bumps 250 arranged under each of the plurality of semiconductor chips 400.

The second semiconductor substrate 401, the second passivation layer 410, the second front structure 420, the second front pads 432, and the second rear pads 431 may respectively have substantially the same configurations as the second semiconductor substrate 201, the second passivation layer 210, the second front structure 220, the second front pads 232, and the second rear pads 231 illustrated in FIGS. 1 and 2, and a detailed description thereof may be omitted.

In one or more embodiments, the plurality of adhesive layers 460 may be configured to fix the plurality of semiconductor chips 400 to the base chip 100. The plurality of adhesive layers 460 may surround side surfaces of the plurality of connection bumps 250. The plurality of adhesive layers 460 may be arranged between the base chip 100 and the plurality of semiconductor chips 400 to contact and surround the plurality of connection bumps 250. The plurality of adhesive layers 460 may include an NCF. However, embodiments are not limited thereto. For example, the adhesive layers 460 may include at least one of an epoxy resin, silica (SiO₂), and acrylic copolymer, or a combination thereof.

In one or more embodiments, the plurality of adhesive layers 460 may simultaneously cover a lower surface and side surfaces of each of the plurality of semiconductor chips 400 adjacent in the vertical direction (Z direction) among the plurality of semiconductor chips 400. For example, the first adhesive layer 460a may simultaneously cover a lower surface and side surfaces of the first semiconductor chip 400a, a lower surface and side surfaces of the second semiconductor chip 400b, and a lower surface and side surfaces of the third semiconductor chip 400c. In addition, the first adhesive layer 460a may simultaneously cover a lower surface and side surfaces of the fourth semiconductor chip 400d, a lower surface and side surfaces of the fifth semiconductor chip 400e, and a lower surface and side surfaces of the sixth semiconductor chip 400f. The first adhesive layer 460a and the second adhesive layer 460b may be formed as a single body to simultaneously cover the lower surface and side surfaces of each of the adjacent plurality of semiconductor chips 400.

In one or more embodiments, each of the plurality of adhesive layers 460 may include a plurality of horizontal portions 461a, 461b, 461c, 461d, 461e, and 461f for covering lower surfaces of the plurality of semiconductor chips 400 and first and second vertical portions 462a and 462b for covering side surfaces of the plurality of semiconductor chips 400. That is, each of the plurality of adhesive layers 460 may include a plurality of horizontal portions 461a, 461b, 461c, 461d, 461e, and 461f that overlap the plurality of semiconductor chips 400 in the vertical direction (Z direction), and first and second vertical portions 462a and 462b that cover the side surfaces of the plurality of semiconductor chips 400 and protrude outwards from the plurality of horizontal portions 461a, 461b, 461c, 461d. 461e, and 461f. The first and second vertical portions 462a and 462b may be mentioned as fillet portions. The degree of protrusion and shape of the first and second vertical portions 462a and 462b may vary depending on process conditions, for example, conditions of a thermal compression process.

In one or more embodiments, the first adhesive layer 460a may include the first horizontal portion 461a, the second horizontal portion 461b, the third horizontal portion 461c, and the first vertical portion 462a. The first horizontal portion 461a, the second horizontal portion 461b, the third horizontal portion 461c, and the first vertical portion 462a may be formed as a single body. The second adhesive layer 260b may include a fourth horizontal portion 461d, a fifth horizontal portion 461e, a sixth horizontal portion 461f, and a second vertical portion 462b. The fourth horizontal portion 461d, the fifth horizontal portion 461e, the sixth horizontal portion 461f, and the second vertical portion 462b may be formed as a single body.

In one or more embodiments, the plurality of horizontal portions 461a, 461b, 461c, 461d, 461e, and 461f may be arranged in the vertical direction (Z direction) spaced apart from each other with a plurality of semiconductor chips 400 therebetween. For example, a first semiconductor chip 400a may be disposed between the first horizontal portion 461a and the second horizontal portion 461b, a second semiconductor chip 400b may be disposed between the second horizontal portion 461b and the third horizontal portion 461c, a third semiconductor chip 400c may be disposed between the third horizontal portion 461c and the fourth horizontal portion 461d, a fourth semiconductor chip 400d may be disposed between the fourth horizontal portion 461d and the fifth horizontal portion 461e, and a fifth semiconductor chip 400e may be disposed between the fifth horizontal portion 461e and the sixth horizontal portion 461f.

In one or more embodiments, the first vertical portion 462a may cover side surfaces of the first semiconductor chip 400a, side surfaces of the second semiconductor chip 400b, and side surfaces of the third semiconductor chip 400c. One side of the first vertical portion 462a may be connected to each of the first horizontal portion 461a, the second horizontal portion 461b, and the third horizontal portion 461c. In addition, the other surface of the first vertical portion 462a opposing the one surface may constitute a curved surface. The second vertical portion 462b may cover the side surfaces of the fourth semiconductor chip 400d, the side surfaces of the fifth semiconductor chip 400e, and the side surfaces of the sixth semiconductor chip 400f. The second vertical portion 462b may cover only part of the side surfaces of the sixth semiconductor chip 400f. However, embodiments are not limited thereto. One side of the second vertical portion 462b may be connected to each of the fourth horizontal portion 461d, the fifth horizontal portion 461e, and the sixth horizontal portion 461f. In addition, the other surface of the second vertical portion 462b opposing the one surface may constitute a curved surface. For example, the other surfaces of the first vertical portion 462a and the second vertical portion 462b may have semicircular shapes in a plan view.

In one or more embodiments, a horizontal width l₂ of the first vertical portion 462a may increase and then decrease as the first vertical portion 462a moves away from (e.g., in the Z direction from) the bottom surface of the first adhesive layer 460a. For example, the horizontal width l₂ of the first vertical portion 462a may be maximum at the vertical level of the vertical direction (Z direction) center of the first vertical portion 462a. However, embodiments are not limited thereto. The horizontal width of the second vertical portion 462b may increase and then decrease as the second vertical portion 462b moves away from (e.g., in the Z direction from) the bottom surface of the second adhesive layer 460b. For example, the horizontal width of the second vertical portion 462b may be maximum at the vertical level of the vertical direction (Z direction) center of the second vertical portion 462b. However, embodiments are not limited thereto. The shapes of the first vertical portion 462a and the second vertical portion 462b may be substantially the same or similar. In addition, the horizontal widths of the first vertical portion 462a and the second vertical portion 462b may be substantially the same or similar. However, embodiments are not limited thereto, and the shapes and/or the horizontal widths of the first vertical portion 462a and the second vertical portion 462b may be different from each other.

In the semiconductor package 20 according to one or more embodiments, the plurality of semiconductor chips 400 may be adhered to each other using one adhesive layer 460. For example, the first semiconductor chip 400a, the second semiconductor chip 400b, and the third semiconductor chip 400c may be simultaneously adhered to each other using the first adhesive layer 460a, and the fourth semiconductor chip 400d, the fifth semiconductor chip 400e, and the sixth semiconductor chip 400f may be simultaneously adhered to each other using the second adhesive layer 460b. Thus, the first and second vertical portions 462a and 462b of the adhesive layer 460 may be formed as a single body to cover the side surfaces of three or more semiconductor chips 400, so that the number of fillets may be reduced as compared to the comparative example. In addition, since the first and second vertical portions 462a and 462b are formed as a single body, the horizontal lengths of the first and second vertical portions 462a and 462b may be reduced, so that warpage of the semiconductor package 20 is reduced and thus the reliability of the semiconductor package 20 may be increased. In addition, the horizontal lengths of the first and second vertical portions 462a and 462b may be reduced, and stress acting between the interface of the first and second vertical portions 462a and 462b and the encapsulation layer 300 of the semiconductor package 20 may be reduced so that cracks may be reduced.

In addition, the first semiconductor chip 400a, the second semiconductor chip 400b, and the third semiconductor chip 400c may be simultaneously adhered to each other using the first adhesive layer 460a, and the fourth semiconductor chip 400d, the fifth semiconductor chip 400e, and the sixth semiconductor chip 400f may be simultaneously adhered to each other using the second adhesive layer 460b so that the productivity of the semiconductor package 20 may be enhanced.

In FIGS. 1 and 4, in the semiconductor packages 10 and 20, only two or three semiconductor chips 200 and 400 are adhered to each other using one adhesive layer 260 or 460. However, embodiments are not limited thereto. For example, four or more semiconductor chips may be adhered to each other using one adhesive layer. In addition, in one semiconductor package, a plurality of adhesive layers may be used to adhere a different number of semiconductor chips. For example, the first adhesive layer may be used to adhere two semiconductor chips simultaneously, and the second adhesive layer may be used to adhere three semiconductor chips simultaneously.

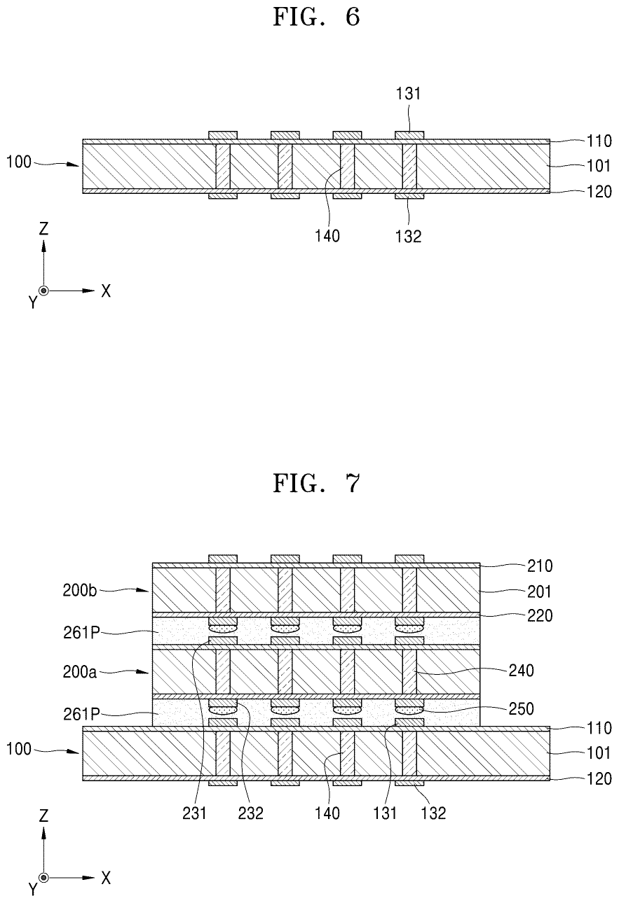

FIGS. 6 through 11 are cross-sectional views sequentially illustrating a method of fabricating a semiconductor package according to one or more embodiments.

In the description with reference to FIGS. 6 through 11, the same reference numerals as in FIGS. 1 and 2 represent the same elements, and detailed descriptions thereof may be omitted.

Referring to FIG. 6, the base chip 100 may be prepared. The base chip 100 may include a first semiconductor substrate 101, a first passivation layer 110, a first front structure 120, first front pads 132, first rear pads 131, and first through electrodes 140.

Referring to FIG. 7, a first semiconductor chip 200a and a second semiconductor chip 200b may be sequentially attached to the base chip 100. Each of the first semiconductor chip 200a and the second semiconductor chip 200b may include a second semiconductor substrate 201, a second passivation layer 210, a second front structure 220, second front pads 232, second rear pads 231, and second through electrodes 240.

A preliminary adhesive layer 261P may be disposed between the base chip 100 and the first semiconductor chip 200a, and between the first semiconductor chip 200a and the second semiconductor chip 200b. The preliminary adhesive layer 261P may include an NCF. However, embodiments are not limited thereto. Each of the plurality of connection bumps 250 may be aligned with the first rear pads 131 or the second rear pads 231.

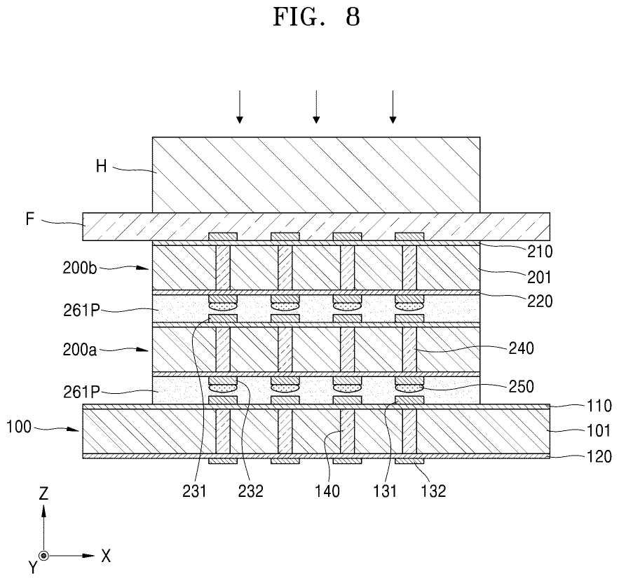

Referring to FIG. 8, the first semiconductor chip 200a and the second semiconductor chip 200b may be adhered to the base chip 100 through a thermal compression process. Heat and pressure may be applied in the vertical direction (Z direction) to the first semiconductor chip 200a and the second semiconductor chip 200b through a bonding head H. A release film F may be disposed between the second semiconductor chip 200b and the bonding head H.

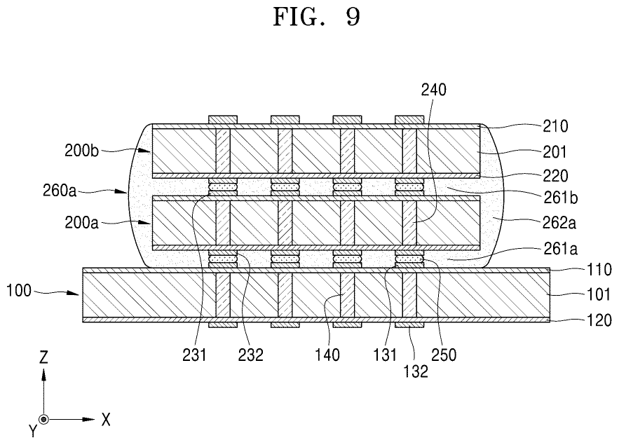

Referring to FIG. 9, as a result of the thermal compression process, the preliminary adhesive layer 261P may be reflowed and cured to form a first adhesive layer 260a. The first adhesive layer 260a may simultaneously cover the lower surface and the side surfaces of the first semiconductor chip 200a and the lower surface and the side surfaces of the second semiconductor chip 200b. The first adhesive layer 260a may include a first horizontal portion 261a disposed between the base chip 100 and the first semiconductor chip 200a, a second horizontal portion 261b disposed between the first semiconductor chip 200a and the second semiconductor chip 200b, and a first vertical portion 262a covering the side surfaces of the first semiconductor chip 200a and the second semiconductor chip 200b. The first horizontal portion 261a, the second horizontal portion 261b, and the first vertical portion 262a may be formed as a single body.

A process recipe may be controlled in such a way that the plurality of connection bumps 250 arranged between the base chip 100 and the first semiconductor chip 200a and between the first semiconductor chip 200a and the second semiconductor chip 200b may be simultaneously adhered to each other.

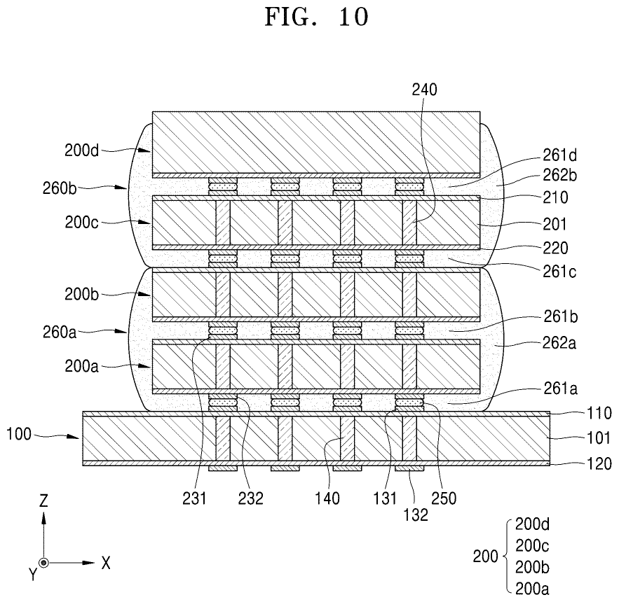

Referring to FIG. 10, by performing the processes of FIGS. 7 through 9 repeatedly, the third semiconductor chip 200c and the fourth semiconductor chip 200d may be sequentially adhered to the second semiconductor chip 200b and may be adhered to each other through the thermal compression process.

As a result of the thermal compression process, a preliminary adhesive layer may be reflowed and cured to form a second adhesive layer 260b. The second adhesive layer 260b may simultaneously cover a lower surface and side surfaces of the third semiconductor chip 200c and a lower surface and side surfaces of the fourth semiconductor chip 200d. The second adhesive layer 260b may include a third horizontal portion 261c disposed between the second semiconductor chip 200b and the third semiconductor chip 200c, a fourth horizontal portion 261d disposed between the third semiconductor chip 200c and the fourth semiconductor chip 200d, and a second vertical portion 262b covering the side surfaces of the third semiconductor chip 200c and the fourth semiconductor chip 200d. The third horizontal portion 261c, the fourth horizontal portion 261d, and the second vertical portion 262b may be formed as a single body.

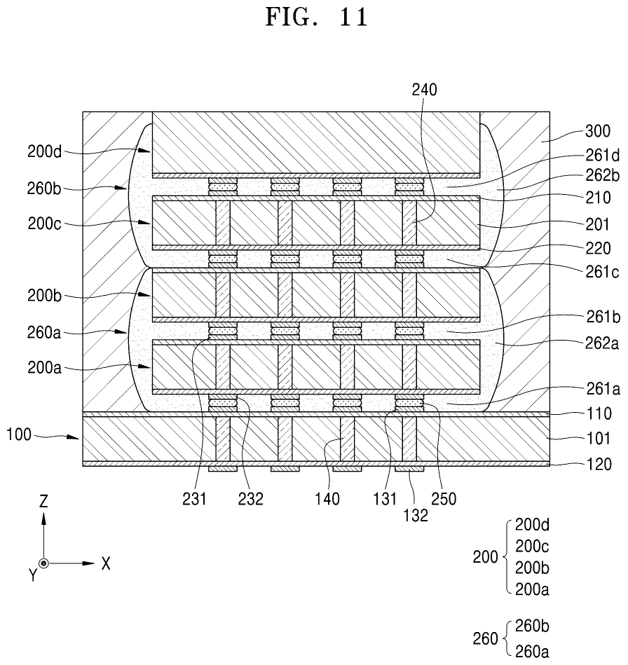

Referring to FIG. 11, the encapsulation layer 300 covering the result of FIG. 10 may be formed. The encapsulation layer 300 may cover the upper surface of the base chip 100, and the side surfaces of the plurality of semiconductor chips 200 and the plurality of adhesive layers 260.

Subsequently, referring back to FIG. 1, lower bumps 150 may be formed under the base chip 100 so that the semiconductor package 10 according to one or more embodiments may be fabricated. The lower bumps 150 may be connected to the first front pads 132 and electrically connected to the base chip 100.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a base chip;
a first semiconductor chip group comprising a plurality of first semiconductor chips stacked on the base chip in a vertical direction;
a second semiconductor chip group comprising a plurality of second semiconductor chips stacked on the first semiconductor chip group in the vertical direction;
a plurality of first connection bumps on lower surfaces of the plurality of first semiconductor chips;
a plurality of second connection bumps on lower surfaces of the plurality of second semiconductor chips;
a first adhesive layer surrounding the plurality of first connection bumps and the first semiconductor chip group; and
a second adhesive layer surrounding the plurality of second connection bumps and the second semiconductor chip group.

2. The semiconductor package of claim 1, wherein the plurality of first semiconductor chips comprise a first semiconductor chip and a second semiconductor chip stacked in the vertical direction,
wherein the first adhesive layer comprises a single body covering a lower surface and side surfaces of the first semiconductor chip and a lower surface and side surfaces of the second semiconductor chip,
wherein the plurality of second semiconductor chips comprise a third semiconductor chip and a fourth semiconductor chip stacked in the vertical direction, and
wherein the second adhesive layer comprises a single body covering a lower surface and side surfaces of the third semiconductor chip and a lower surface and side surfaces of the fourth semiconductor chip.

3. The semiconductor package of claim 1, wherein the first adhesive layer comprises a plurality of first horizontal portions covering each lower surface of the plurality of first semiconductor chips and a first vertical portion covering each side surface of the plurality of first semiconductor chips, and
wherein the second adhesive layer comprises a plurality of second horizontal portions covering each lower surface of the plurality of second semiconductor chips and a second vertical portion covering each side surface of the plurality of second semiconductor chips.

4. The semiconductor package of claim 3, wherein the first vertical portion comprises a first surface connected to each of the plurality of first horizontal portions, and a second surface that is opposite to the first surface and that is curved, and
wherein the second vertical portion comprises a third surface connected to each of the plurality of second horizontal portions, and a fourth surface that is opposite to the third surface and that is curved.

5. The semiconductor package of claim 4, wherein a horizontal width of the first vertical portion increases and then decreases in the vertical direction from a bottom surface of the first adhesive layer, and
wherein a horizontal width of the second vertical portion increases and then decreases in the vertical direction from a bottom surface of the second adhesive layer.

6. The semiconductor package of claim 1, wherein each of the plurality of first semiconductor chips and the plurality of second semiconductor chips comprises:
a semiconductor substrate comprising through electrodes;
a front structure covering a lower surface of the semiconductor substrate and comprising a plurality of devices;
a passivation layer covering an upper surface of the semiconductor substrate; and
a plurality of pads connected to the through electrodes.

7. The semiconductor package of claim 1, wherein a number of the plurality of first semiconductor chips is different from a number of the plurality of second semiconductor chips.

8. A semiconductor package comprising:
a base chip;
a first semiconductor chip and a second semiconductor chip stacked on the base chip in a vertical direction;
a plurality of first connection bumps between the base chip and the first semiconductor chip, and between the first semiconductor chip and the second semiconductor chip;
a first adhesive layer surrounding the plurality of first connection bumps; and
an encapsulation layer covering an upper surface of the base chip, the first semiconductor chip, the second semiconductor chip, and the first adhesive layer,
wherein the first adhesive layer comprises a single body covering a lower surface and side surfaces of the first semiconductor chip and a lower surface and side surfaces of the second semiconductor chip.

9. The semiconductor package of claim 8, further comprising:
a third semiconductor chip stacked on the second semiconductor chip in the vertical direction,
wherein the first adhesive layer further covers a lower surface and side surfaces of the third semiconductor chip.

10. The semiconductor package of claim 8, wherein the first adhesive layer comprises:
a first horizontal portion between the base chip and the first semiconductor chip;
a second horizontal portion between the first semiconductor chip and the second semiconductor chip; and
a first vertical portion covering side surfaces of the first semiconductor chip and side surfaces of the second semiconductor chip, and
wherein the first horizontal portion, the second horizontal portion, and the first vertical portion comprise a single body.

11. The semiconductor package of claim 10, wherein a first surface of the first vertical portion is connected to the first horizontal portion and the second horizontal portion, and
a second surface of the first vertical portion that is opposite to the first is curved.

12. The semiconductor package of claim 11, wherein a horizontal width of the first vertical portion increases and then decreases in the vertical direction from a bottom surface of the first adhesive layer.

13. The semiconductor package of claim 12, wherein a horizontal width of the first vertical portion is largest in a center of the first vertical portion in the vertical direction.

14. The semiconductor package of claim 8, further comprising:
a third semiconductor chip and a fourth semiconductor chip stacked on the second semiconductor chip in the vertical direction;
a plurality of second connection bumps between the second semiconductor chip and the third semiconductor chip, and between the third semiconductor chip and the fourth semiconductor chip; and
a second adhesive layer comprising a single body covering a lower surface and side surfaces of the third semiconductor chip and a lower surface and side surfaces of the fourth semiconductor chip.

15. The semiconductor package of claim 14, wherein the second adhesive layer comprises:
a third horizontal portion between the second semiconductor chip and the third semiconductor chip;
a fourth horizontal portion between the third semiconductor chip and the fourth semiconductor chip; and
a second vertical portion covering side surfaces of the third semiconductor chip and side surfaces of the fourth semiconductor chip, and
wherein the third horizontal portion, the fourth horizontal portion, and the second vertical portion comprise a single body.

16. The semiconductor package of claim 14, wherein the encapsulation layer covers the third semiconductor chip, the fourth semiconductor chip, and the second adhesive layer.

17. A method of fabricating a semiconductor package, the method comprising:
preparing a base chip;
providing a first semiconductor chip on the base chip in a vertical direction;
providing a second semiconductor chip on the first semiconductor chip in the vertical direction; and
thermally compressing the first semiconductor chip and the second semiconductor chip onto the base chip by performing first thermal compression,
wherein the performing of the first thermal compression comprises forming a first adhesive layer as a single body covering a lower surface and side surfaces of the first semiconductor chip, and a lower surface and side surfaces of the second semiconductor chip.

18. The method of claim 17, further comprising:
providing a third semiconductor chip on the second semiconductor chip in the vertical direction;
providing a fourth semiconductor chip on the third semiconductor chip in the vertical direction; and
thermally compressing the third semiconductor chip and the fourth semiconductor chip onto the second semiconductor chip by performing second thermal compression,
wherein the performing of the second thermal compression comprises forming a second adhesive layer as a single body covering a lower surface and side surfaces of the third semiconductor chip, and a lower surface and side surfaces of the fourth semiconductor chip.

19. The method of claim 17, wherein the performing of the first thermal compression further comprises simultaneously adhering a plurality of connection bumps arranged between the base chip and the first semiconductor chip and between the first semiconductor chip and the second semiconductor chip.

20. The method of claim 17, further comprising providing a third semiconductor chip on the second semiconductor chip in the vertical direction,
wherein the performing of the first thermal compression further comprises forming the first adhesive layer as a single body covering a lower surface and side surfaces of the first semiconductor chip, a lower surface and side surfaces of the second semiconductor chip, and a lower surface and side surfaces of the third semiconductor chip.
